(19) United States
(12) Patent Application Publication
(10) Pub. No.: US 2025/0210601 A1
(43) Pub. Date: Jun. 26, 2025

(54) PIXEL ARRAY AND MANUFACTURING METHOD THEREFOR

(71) Applicant: Wuhan Tuopu Jingyan Semiconductor Technology Co. Ltd., Wuhan (CN)

(72) Inventors: Ying QIN, Wuhan (CN); Yifei ZHANG, Wuhan (CN); Lina CHEN, Wuhan (CN)

(21) Appl. No.: 18/588,973

(22) Filed: Feb. 27, 2024

(30) Foreign Application Priority Data
Dec. 21, 2023 (CN) 202311784429.X

(51) Int. Cl. H01L 25/10; H01L 23/00; H01L 27/15

(52) U.S. Cl. CPC H01L 25/105; H01L 24/29; H01L 24/32; H10H 29/142; H01L 2224/29028; H01L 2224/32245

(57) ABSTRACT

The present disclosure relates to a pixel array and manufacturing method therefor. The method includes providing a bare wafer including a complementary metal oxide semiconductor, providing a native substrate, forming pixel structures arranged at intervals on the native substrate, forming a bonding isolation layer with multi-layer structure. The bonding isolation layer is located between adjacent pixel structures distributed along a first direction and covers the exposed surfaces of the pixel structures to obtain a light-emitting chip. The light-emitting chip includes at least one of the pixel structures distributed along the first direction or a second direction. The first direction is parallel to a top surface of the native substrate, and the second direction is perpendicular to the top surface of the native substrate. The pixel structures of a plurality of the light-emitting chips are bonded to the bare wafer, with top surfaces of the light-emitting chips facing the bare wafer.

### CROSS-REFERENCE TO RELATED APPLICATIONS

This application claims priority to Chinese patent application No. 202311784429X filed with the Chinese Patent Office on Dec. 21, 2023, entitled “PIXEL ARRAY AND MANUFACTURING METHOD THEREFOR”, the entire content of which is incorporated by reference.

### TECHNICAL FIELD

The present disclosure relates to the technical field of semiconductor, and particularly to a pixel array and a manufacturing method therefor.

### BACKGROUND

In the field of semiconductor manufacturing, under certain conditions, a new monocrystalline layer that meets the requirements of conductivity type, resistivity, thickness, lattice structure, integrity, etc., can be grown along the original crystallographic direction on a carefully prepared single substrate, and the grown monocrystalline layer is called an epitaxial layer. In the field of compound semiconductor technology, a Complementary Metal Oxide Semiconductor (CMOS) substrate and a compound semiconductor epitaxial wafer are usually bonded together, thus the compound semiconductor dies are bonded to the CMOS substrate to achieve functional control.

### SUMMARY

According to various embodiments of the present disclosure, one aspect of the present disclosure provides a method for manufacturing a pixel array. In the method, a bare wafer including a complementary metal oxide semiconductor is provided. A native substrate is provided and pixel structures arranged at intervals are formed on the native substrate. A bonding isolation layer with a multi-layer structure is formed, which is located between adjacent pixel structures distributed along a first direction and covers exposed surfaces of the pixel structures, thereby obtaining a light-emitting chip. The light-emitting chip includes at least one pixel structure arranged at intervals along the first direction or a second direction. The first direction is parallel to a top surface of the native substrate, and the second direction is perpendicular to the top surface of the native substrate. The pixel structures of a plurality of light-emitting chips are bonded to the bare wafer, with top surfaces of the light-emitting chips facing the bare wafer.

In some embodiments, the forming the pixel structures arranged at intervals on the native substrate includes forming a patterned mask layer on the native substrate, the patterned mask layer including opening patterns arranged at intervals along the first direction, the opening patterns exposing part of the native substrate; forming first semiconductor layer in the opening patterns, respectively, with the top surface of the first semiconductor layers being flush and higher than a top surface of the patterned mask layer; forming active layers covering outer surfaces of the first semiconductor layers, respectively, and arranged at intervals along the first direction; forming second semiconductor layers covering outer surfaces of the active layers, respectively, and arranged at intervals along the first direction. Each pixel structure is jointly formed by one first semiconductor layer, one active layer, and one second semiconductor layer that are sequentially stacked in a direction perpendicular to the native substrate. A conductivity type of the first semiconductor layer is opposite to that of the second semiconductor layer.

In some embodiments, the forming the pixel structures arranged at intervals on the native substrate includes forming a patterned mask layer on the native substrate, the patterned mask layer including opening patterns arranged at intervals along the first direction, and the opening patterns exposing part of the native substrate; forming first semiconductor layers in the opening patterns, respectively, with top surfaces of the first semiconductor layers being flush and higher than a top surface of the patterned mask layer; forming an initial bonding isolation layer on the patterned mask layer, a top surface of the initial bonding isolation layer being flush with the top surfaces of the first semiconductor layers, and the initial bonding isolation layer being located between adjacent first semiconductor layers that are arranged along the first direction; forming active layers on the top surfaces of the first semiconductor layers, respectively; and forming second semiconductor layers on top surfaces of the active layers, respectively. Each pixel structure is jointly formed by one first semiconductor layer, one active layer, and one second semiconductor layer that are sequentially stacked in a direction perpendicular to the native substrate. A conductivity type of the first semiconductor layer is opposite to that of the second semiconductor layer.

In some embodiments, after forming the bonding isolation layer and before bonding the pixel structures of the plurality of light-emitting chips to the bare wafer, the method further includes bonding the bonding isolation layers of the plurality of the light-emitting chips to different areas arranged at intervals on a spliced substrate; removing parts of the spliced substrate and the bonding isolation layer that are higher than top surfaces of the pixel structures to expose the top surfaces of the pixel structures; forming a target transparent conductive layer on the top surface of the pixel structures of each light-emitting chip; and forming a reflective conductive layer covering the top surface of the target transparent conductive layer.

In some embodiments, the forming the pixel structures arranged at intervals on the native substrate includes forming a patterned mask layer on the native substrate, the patterned mask layer comprising opening patterns arranged at intervals along the first direction, and the opening patterns exposing parts of the native substrate; forming first semiconductor layers in the opening patterns, with the top surfaces of the first semiconductor layers being flush and higher than a top surface of the patterned mask layer; forming an initial bonding isolation layer on the patterned mask layer, a top surface of the initial bonding isolation layer being flush with the top surfaces of the first semiconductor layers, the initial bonding isolation layer being located between adjacent first semiconductor layers that are arranged along the first direction; forming active layers on the top surfaces of the first semiconductor layers, respectively; and forming second semiconductor layers on the top surfaces of the active layers, respectively. Each pixel structure is jointly formed by one first semiconductor layer, one active layer, and one second semiconductor layer that are sequentially stacked in a direction perpendicular to the native substrate. A conductivity type of the first semiconductor layer is opposite to that of the second semiconductor layer.

In some embodiments, the forming the bonding isolation layer further includes form a bonding isolation layer on the initial bonding isolation layer, a top surface of the bonding isolation layer being flush with the top surfaces of the second semiconductor layers, thereby obtaining an initial epitaxial wafer. After forming the bonding isolation layer, the method also includes providing a plurality of initial epitaxial wafers; forming a first transparent conductive layer on a first initial epitaxial wafer and forming a second transparent conductive layer on a second initial epitaxial wafer, where the first transparent conductive layer covers a top surface of an intermediate bonding isolation layer and the top surfaces of the second semiconductor layers of the first initial epitaxial wafer on which the first transparent conductive layer is located, and the second transparent conductive layer covers a top surface of an intermediate bonding isolation layer and the top surfaces of the second semiconductor layers on which the initial epitaxial wafer is located; after a top surface of the first transparent conductive layer is bonded to a top surface of the second transparent conductive layer, removing the native substrate of the first initial epitaxial wafer on which the first transparent conductive layer is located, thereby obtaining an intermediate epitaxial wafer; forming a first transparent electrode extending to a top surface of a remaining native substrate along a direction perpendicular to the native substrate and a second transparent electrode extending to the first transparent conductive layer in the intermediate epitaxial wafer, thereby obtaining the light-emitting chip.

In some embodiments, the bonding the pixel structures of the plurality of light-emitting chips to the bare wafer includes forming a conductive bonding layer on a top surface of the bare wafer; and bonding the plurality of light-emitting chips to corresponding positions on the conductive bonding layer, with top surfaces of the light-emitting chips facing the bare wafer.

In some embodiments, bonding the plurality of light-emitting chips to the conductive bonding layer, the method further includes removing a substrate located on sides of the pixel structures away from the bare wafer along a direction perpendicular to the bare wafer, the substrate comprising a spliced substrate or the native substrate; and forming a common electrode electrically connected to at least one of the light-emitting chips.

In some embodiments, the forming the patterned mask layer on the native substrate includes forming a mask layer on the top surface of the native substrate; forming a patterned photoresist layer on a top surface of the mask layer; etching the mask layer by using the patterned photoresist layer as a mask to obtain the patterned mask layer; and removing a remaining part of the patterned photoresist layer.

In some embodiments, before bonding the pixel structures of the plurality of light-emitting chips to the bare wafer, the method further includes forming a reflective cup structure on left and right sides of the light-emitting chip on the native substrate. The reflective cup structure includes a reflective medium layer and transparent medium layers located on left and right sides of the reflective medium layer.

In some embodiments, after bonding the pixel structures of the plurality of light-emitting chips to the bare wafer to form the pixel array, the method further includes: forming a blocking layer on a top surface of the pixel array; forming a reflector layer on a top surface of the blocking layer; forming a Bragg reflector layer on a top surface of the reflector layer; and forming a second reflector on a top surface of the Bragg reflector layer.

In some embodiments, the reflector layer includes a first sub-reflector, a transparent medium layer, and reflective structures located on left and right sides of the first sub-reflector. Each reflective structure includes a second sub-reflector and a first reflective layer surrounding the second sub-reflector, and the transparent medium layer fills a gap between the first sub-reflector and the reflective structures.

In some embodiments, after bonding the pixel structures of the plurality of light-emitting chips to the bare wafer to form the pixel array, the method further includes: forming a first reflector layer on a top surface of the pixel array; forming a blocking layer on a top surface of the first reflector layer; forming a reflector layer on a top surface of the blocking layer; forming a Bragg reflector layer on a top surface of the reflector layer; and forming a second reflector on a top surface of the Bragg reflector layer.

In some embodiments, the first reflector layer includes a reflector, a reflective medium layer located on both sides of the reflector, and a transparent medium layer filling a gap between the reflector and the reflective medium layer.

In some embodiments, after bonding the pixel structures of the plurality of light-emitting chips to the bare wafer to form the pixel array, the method further includes: forming a first reflector layer on a top surface of the pixel array; forming a first Bragg reflector layer on a top surface of the first reflector layer; forming a reflector layer on a top surface of the first Bragg reflector layer; forming a second Bragg reflector layer on a top surface of the reflector layer; and forming a second reflector on a top surface of the second Bragg reflector layer.

In some embodiments, before bonding the pixel structures of the plurality of light-emitting chips to the bare wafer and after forming each light-emitting chip with the reflective cup structure, the method further includes forming a bottom reflective layer on a bottom surface of each light-emitting chip.

In some embodiments, an inclination angle of the reflective cup is 55 degrees to 65 degrees.

In some embodiments, another aspect of the present disclosure provides a pixel array manufactured by any of the above methods for manufacturing a pixel array.

### BRIEF DESCRIPTION OF DRAWINGS

In order to illustrate the technical solutions in the embodiments of the present disclosure or prior art more clearly, the accompanying drawings used in the description of the embodiments or prior art will be briefly introduced below. Apparently, the accompanying drawings in the following description are only some embodiments of the present disclosure. For those of ordinary skill in the art, other drawings can also be derived from these drawings without creative effort.

FIG. 1 is a schematic flowchart of a method for manufacturing a pixel array according to an embodiment of the present disclosure.

FIGS. 2a-2d are schematic diagrams showing processes of a method for manufacturing a pixel array according to an embodiment of the present disclosure.

FIG. 2a′ is a schematic cross-sectional view of a pixel array according to an embodiment of the present disclosure.

FIG. 3 is a schematic diagram showing a process of a method for manufacturing a pixel array according to another embodiment of the present disclosure.

FIG. 4 is a schematic cross-sectional view of a pixel array according to another embodiment of the present disclosure.

FIG. 5 is a schematic flowchart of a method for manufacturing a pixel array according to yet another embodiment of the present disclosure.

FIG. 6 is a schematic diagram showing a process of a method for manufacturing a pixel array according to yet another embodiment of the present disclosure.

FIG. 7 is a schematic cross-sectional view of a pixel array according to yet another embodiment of the present disclosure.

FIG. 8 is a schematic flowchart of a method for manufacturing a pixel array according to yet another embodiment of the present disclosure.

FIG. 9 is a schematic diagram showing a process of a method for manufacturing a pixel array according to yet another embodiment of the present disclosure.

FIG. 10 is a schematic cross-sectional view of a pixel array according to yet another embodiment of the present disclosure.

FIG. 11 is a schematic cross-sectional view of a pixel array with a reflective cup structure according to an embodiment of the present disclosure.

FIGS. 12a-12c are schematic cross-sectional views of pixel arrays, each of which includes a reflective cup structure, a reflective mirror, a blocking layer, and a Bragg mirror layer, according to some embodiments of the present disclosure.

FIGS. 13a-13b are schematic top views of pixel units according to some embodiment of the present disclosure.

FIGS. 14a-14d are schematic diagrams each showing a reflected light path of a pixel array according to an embodiment of the present disclosure.

FIG. 15 is a schematic cross-sectional view of a pixel array with an underlying reflective layer structure according to an embodiment of the present disclosure.

FIG. 16a is a schematic cross-sectional view of a reflective cup structure according to an embodiment of the present disclosure, showing the inclination angle and height of the reflective cup structure.

FIGS. 16b-16c are schematic diagrams each showing a simulated reflected light path and color distribution of a reflective cup structure according to an embodiment of the present disclosure.

FIG. 17 shows a schematic diagram of a far-field on-axis intensity and a schematic diagram of an inclination angle at which the brightness attenuates by 50%, obtained based on a simulation measurement of the inclination angle and height of the reflective cup structure according to an embodiment of the present disclosure.

FIG. 18 is a schematic diagram of a simulation of a first sub-reflector that illustrates a relationship between a LED size, toper angle, and light extraction efficiency.

### DETAILED DESCRIPTION OF THE EMBODIMENTS

To facilitate understanding of the present disclosure, the present disclosure will be described more detail below with reference to the relevant accompanying drawings. Preferred embodiments of the present disclosure are illustrated in the accompanying drawings. However, the present disclosure may be implemented in many different forms and is not limited to the embodiments described herein. On the contrary, these embodiments are provided to make the disclosed content of the present disclosure more thorough and comprehensive.

Unless otherwise defined, all technical and scientific terms used herein have the same meaning as commonly understood by one of ordinary skill in the technical field to which the present disclosure belongs. The terms used in the specification of the disclosure are for the purpose of describing specific embodiments only, and are not intended to limit the disclosure.

It should be understood that when an element or layer is referred to as being “on,” “adjacent to” “connected to” or “coupled to” another element or layer, it can be directly located on, adjacent to, connected to, or coupled to another element or layer, or there may be intermediate elements or layers. Conversely, when an element is referred to as being “directly on,” “directly adjacent to”, “directly connected to”, or “directly coupled to” another element or layer, there are no intermediate elements or layers.

Spatial relational terms such as “under”, “below”, “above” in this disclosure may be used to describe a relationship between one element or feature and other elements or features shown in the drawings. It should be understood that in addition to orientations shown in the drawings, the spatial relational terms further include different orientations of a device in use and operation. For example, if the device in the drawing is turned over, elements or features described as “below” or “under” would then be oriented “above” the other elements or features. Thus, the exemplary terms “below” and “under” can include both an orientation of above and below. In addition, the device may also be otherwise oriented (e.g., rotated 90 degrees or at other orientations) and the spatial descriptors used herein interpreted accordingly.

As used herein, the singular forms “a,” “an,” and “this/the” may also include the plural forms, unless otherwise clearly indicated. It should also be understood that the use of the terms “comprise” and/or “include” in this specification may is intended to specify the presence of the stated features, integers, steps, operations, components, and/or parts, but does not exclude the presence or addition of one or more other features, integers, steps, operations, components, parts and/or groups. In addition, as used herein, the term “and/or” includes any and all combinations of the associated listed items.

It should be noted that the drawings provided in the embodiments only illustrate the basic concept of the present disclosure in a schematic manner. Although the drawings only show the components related to the present disclosure and are not drawn in accordance with the actual implementation of the number, shape, and dimension of the components, the configuration, quantity, and proportion of the components can be arbitrarily changed, and the layout of the components may also be more complex.

Under certain conditions, a new monocrystalline layer that meets the requirements of conductivity type, resistivity, thickness, lattice structure, integrity, etc., can be grown along the original crystallographic direction on a carefully prepared single substrate, and the grown monocrystalline layer is called an epitaxial layer. In the field of compound semiconductor technology, a CMOS substrate and a compound semiconductor epitaxial wafer are usually bonded together, thus the compound semiconductor dies are bonded to the CMOS substrate to achieve functional control. Due to the fact that CMOS bare wafers have yield problems, defective products (i.e., defective dies) may be randomly distributed in different positions of the single bare wafer, resulting in yield loss during bonding and wasting compound semiconductor epitaxy. In addition, during the growth of the epitaxial wafer, the unevenness caused by the fluctuations in the growth process may cause regional variations in the characteristics of the epitaxial wafer, leading to performance differences in the bonded products and resulting in yield losses.

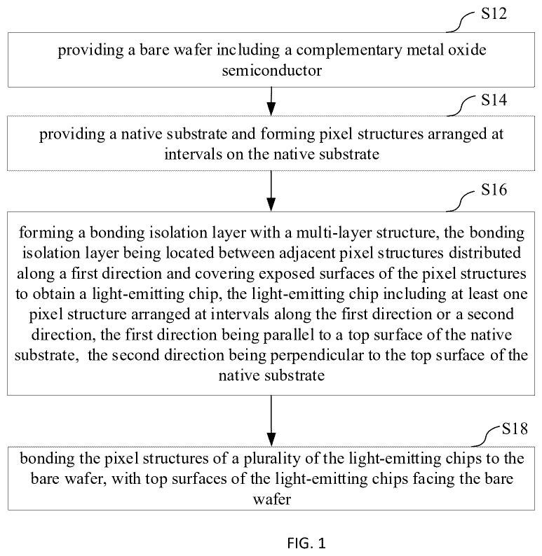

In some embodiments, referring to FIG. 1, an aspect of the present disclosure provides a method for manufacturing a pixel array, which includes the following steps.

In step S12, a bare wafer including a CMOS is provided.

In step S14, a native substrate is provided, and pixel structures arranged at intervals are formed on the native substrate.

In step S16, a bonding isolation layer with a multi-layer structure is formed, and the bonding isolation layer is located between adjacent pixel structures distributed along a first direction and covers the exposed surfaces of the pixel structures, such that a light-emitting chip is obtained. The light-emitting chip includes at least one pixel structure arranged at intervals along the first direction or a second direction. The first direction is parallel to the top surface of the native substrate, and the second direction is perpendicular to the top surface of the native substrate.

In step S18, the pixel structures of a plurality of light-emitting chips are bonded to the bare wafer, with the top surfaces of the light-emitting chips facing the bare wafer.

It should be noted that in some embodiments of the present disclosure, the first direction may be the O-X direction in an X-Y coordinate system, and the second direction may be the O-Y direction in the X-Y coordinate system. The pixel structures may be in a one-to-one correspondence with the complementary metal oxide semiconductor pixels. Alternatively, a plurality of the pixel structures correspond to one complementary metal oxide semiconductor pixel, i.e., the pixel structures are actually sub-pixels.

As an example, with continued reference to FIG. 1, in the method for manufacturing a pixel array in the above embodiment, the light-emitting chip is obtained by forming the pixel structures arranged at intervals on the native substrate and forming the bonding isolation layer covering the exposed surfaces of the pixel structures between adjacent pixel structures distributed along the first direction. The light-emitting chip includes at least one pixel structure arranged at intervals along the first direction or the second direction. The pixel structures of the plurality of light-emitting chips are bonded to the CMOS bare wafer with the top surfaces of the light-emitting chips facing the bare wafer, such that a pixel array is formed. The light-emitting chips with the required performance can be optimally selected, and a patterning process is performed on the pixel arrays on the substrates of various sizes, improving the manufacturing yield and quality of compound semiconductor chips. In the related process, a CMOS substrate and a compound semiconductor epitaxial wafer are bonded together, and the compound semiconductor dies are bonded to the CMOS substrate to achieve functional control. The yield problem of the single CMOS bare wafer cannot be avoided, and defective products (i.e., defective dies) may be randomly distributed in different positions of the CMOS, resulting in yield loss during conventional bonding and wasting compound semiconductor epitaxy. In the method for manufacturing the pixel array provided in the embodiment of the present disclosure, pixel structures arranged at intervals are formed on a native substrate, and a bonding isolation layer covering the exposed surfaces of the pixel structures is formed between adjacent pixel structures that are distributed along a first direction, obtaining a light-emitting chip including at least one pixel structure arranged at intervals along the first direction or the second direction. The light-emitting chips with required performance are optimally selected based on the location of the defective die of the CMOS, and a patterning process is performed on the pixel arrays on the substrates of various sizes, improving the manufacturing yield and quality of compound semiconductor chips.

In some embodiments, the pixel structure includes an electrode and a light-emitting diode (LED) epitaxy. The LED epitaxy includes a plurality of functional layers, such as n-type contact layer (n-Contact), n-type gallium nitride layer (n-GaN), multi-quantum wells (MQWs), electron-blocking layer (EBL), p-type gallium nitride layer (p-GaN), indium tin oxide (ITO) semiconductor transparent conductive film, and p-type contact layer (p-Contact).

In some embodiments, the structure of the functional units on a carrier substrate can be a single layer of the functional units, or it can be multiple vertically stacked layers of the functional units. Different layers of the functional units can come from different types of epitaxial wafers. Different layers of the functional units are connected through patterned or non-patterned transparent electrodes to facilitate subsequent processes to form multi-color devices. The patterned or non-patterned transparent electrodes can be made before the functional units is transferred to the carrier substrate.

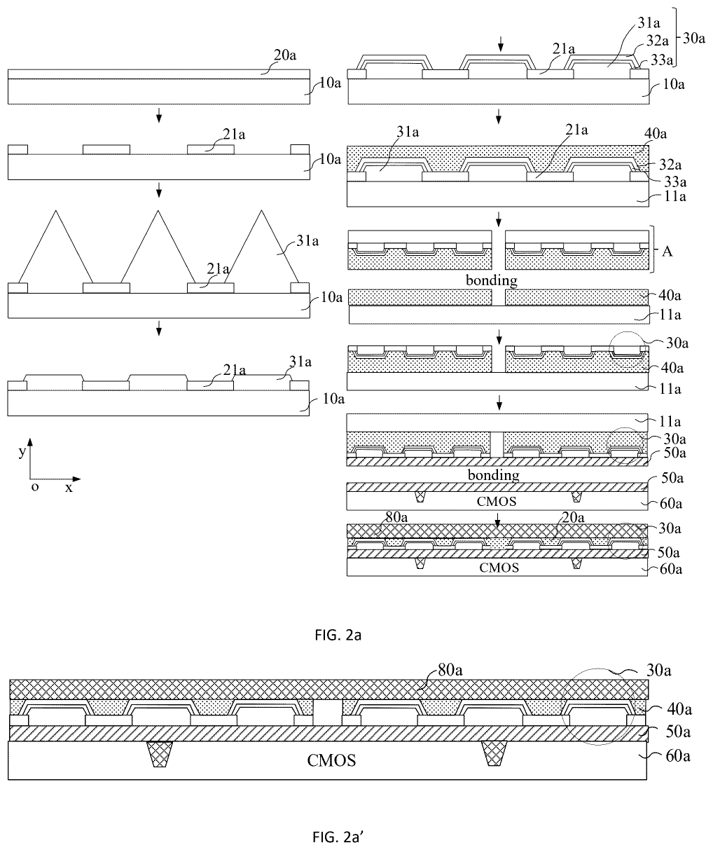

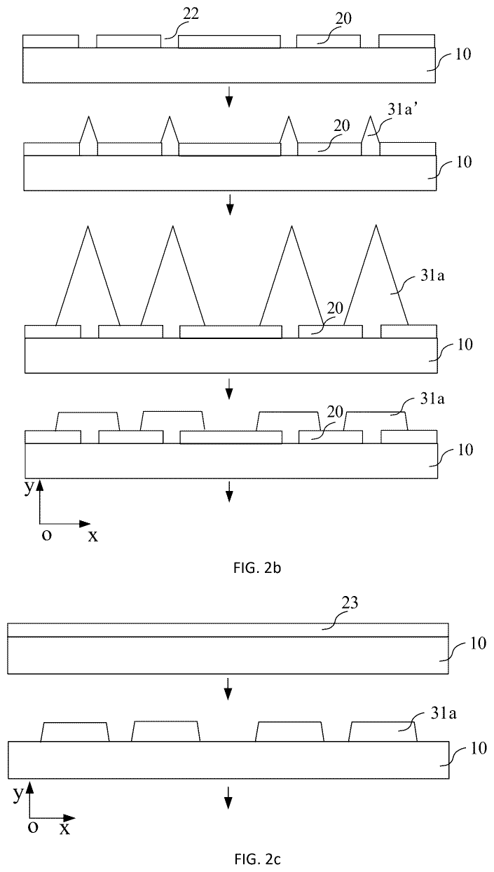

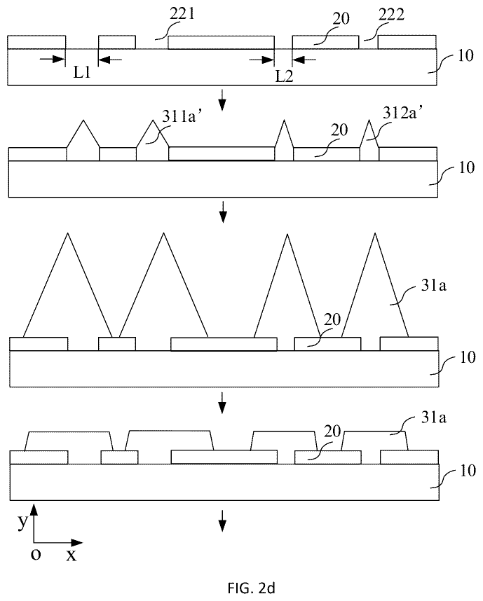

In some embodiments, referring to FIGS. 2a and 2a′, forming the pixel structures 30a arranged at intervals on the native substrate 10a in step S14 includes the following steps.

In step S141, a patterned mask layer 21a is formed on the native substrate 10a, the patterned mask layer 21a includes opening patterns arranged at intervals along the first direction, and the opening patterns expose part of the native substrate 10a.

In step S142, first semiconductor layers 31a are formed in the opening patterns, respectively, and the top surfaces of the first semiconductor layers 31a are flush and higher than the top surface of the patterned mask layer 21a.

In step S143, active layers 33a covering the outer surfaces of the first semiconductor layers 31a, respectively, and arranged at intervals along the first direction are formed.

In step S144, second semiconductor layers 32a covering the outer surfaces of the active layers 33a, respectively, and arranged at intervals along the first direction are formed. Each pixel structure 30a is jointly formed by one first semiconductor layer 31a, one active layer 33a, and one second semiconductor layer 32a that are sequentially stacked in the direction perpendicular to the native substrate 10a. The conductivity type of the first semiconductor layer 31a is opposite to that of the second semiconductor layer 32a.

In some embodiments, with continued reference to FIGS. 2a and 2a′, forming the patterned mask layer 21a on the native substrate 10a in step S141 includes the following steps.

In step S1411, a mask layer 20a is formed on the top surface of the naive substrate 10a.

In step S1412, a patterned photoresist layer is formed on the top surface of the mask layer 20a.

In step S1413, the mask layer 20a is etched by using the patterned photoresist layer as a mask to obtain the patterned mask layer 21a, and the remaining part of the patterned photoresist layer is removed.

As an example, with continued reference to FIGS. 2a and 2a′, forming the patterned photoresist layer (not shown in the figures) on the top surface of the mask layer 20a in step S1412 includes forming a photoresist layer on the top surface of the mask layer 20a and obtaining the patterned photoresist layer through a series of processes such as exposure, development, etc. The patterned photoresist layer includes an opening pattern configured to define parameters such as the position and shape of the mask layer. The photoresist may be a positive photoresist or a negative photoresist. The development method may be positive development or negative development.

As an example, with continued reference to FIGS. 2a and 2a′, in step S1413, the mask layer 20a is etched by wet etching and/or dry etching. For example, the mask layer 20a may be etched using a plasma etching process. Plasma etching refers to a process that utilizes high-frequency glow discharge reaction to activate reaction gas into active particles, such as atoms or free radicals, and these active particles diffuse to the part to be etched and react with the material to be etched, forming volatile products that are removed to achieve the etching. The etching gas may include one or more of the following: CL₂, NF₃, CF₃, HF, CHF₄, etc. Therefore, the etching rate is increased.

In some embodiments, with continued reference to FIGS. 2a and 2a′, bonding the pixel structures 30a of a plurality of light-emitting chips A to the bare wafer 60a in step S18 includes the following steps.

In step S181, a conductive bonding layer 50a is formed on the top surface of the bare wafer 60a.

In step S182, the plurality of light-emitting chips A are bonded to corresponding positions on the conductive bonding layer 50a, with the top surfaces of the light-emitting chips A facing the bare wafer 60a.

In some embodiments, with continued reference to FIGS. 2a and 2a′, after bonding the plurality of light-emitting chips A to the conductive bonding layer 50a in step S182, the method also includes a step S183.

In step S183, the substrate located on the sides of the pixel structures 30a away from the bare wafer along the direction perpendicular to the bare wafer 60a is removed. The substrate includes a spliced substrate 11a or the native substrate 10a. In addition, a common electrode 80a, which is electrically connected to at least one of the light-emitting chips, is formed on the top surfaces of the plurality of light-emitting chips A.

As an example, with continued reference to FIGS. 2a and 2a′, in the above method for manufacturing a pixel array, the pixel structures 30a arranged at intervals are formed on the native substrate 10a, and the bonding isolation layer 40a covering the exposed surfaces of the pixel structures 30a is formed between adjacent pixel structures 30a that are distributed along the first direction, obtaining the light-emitting chip A. The light-emitting chip A includes at least one pixel structure 30a arranged at intervals along the first direction or the second direction. The pixel structures 30a of a plurality of light-emitting chips A are bonded to the CMOS bare wafer 60a, and the top surfaces of the light-emitting chips A face the bare wafer 60a, forming a pixel array. The light-emitting chips with the required performance can be optimally selected, and a patterning process is performed on the pixel arrays on the substrates of various sizes, improving the manufacturing yield and quality of compound semiconductor chips. In the related process, a CMOS substrate and a compound semiconductor epitaxial wafer are bonded together, and the compound semiconductor dies are bonded to the CMOS substrate to achieve functional control. The yield problem of the single CMOS bare wafer cannot be avoided, and defective products (i.e., defective die) may be randomly distributed in different positions of the CMOS, resulting in yield loss during conventional bonding and waste of compound semiconductor epitaxy. In the method for manufacturing a pixel array provided in the embodiments of the present disclosure, pixel structures arranged at intervals are formed on a native substrate, and a bonding isolation layer covering the exposed surfaces of the pixel structures is formed between adjacent pixel structures that are distributed along the first direction, obtaining a light-emitting chip including at least one pixel structure arranged at intervals along the first direction or the second direction. The light-emitting chips with required performance are optimally selected based on the location of the defective die of the CMOS, and a patterning process is performed on the pixel arrays on the substrates of various sizes, improving the manufacturing yield and quality of compound semiconductor chips.

In some embodiments, referring to FIG. 2b, forming the first semiconductor layers 31a in the opening patterns in step S142 further includes forming a patterned mask layer 21a on the native substrate. The patterned mask layer 21a includes grooves 22 arranged at intervals along the first direction, and the opening patterns include the grooves 22. The grooves 22 expose part of the native substrate 10a. A crystal seed layer 31a′ is formed in each of the grooves, and the first semiconductor layer 31a is grown from the crystal seed layer 31a′.

Specifically, the aperture of each groove 22 ranges from 50 nm to 400 nm, such as 50 nm, 100 nm, 150 nm, 200 nm, 250 nm, 300 nm, 350 nm, or 400 nm. The spacing between the grooves 22 ranges from 400 nm to 2000 nm, such as 400 nm, 600 nm, 800 nm, 1000 nm, 1400 nm, 1800 nm or 2000 nm.

In some embodiments, referring to FIG. 2c, the first semiconductor layers 31a may also be formed by forming a seed layer 23 on the native substrate 10a and etching the seed layer 23 according to a patterned mask layer (not shown in the figures).

In some embodiments, referring to FIG. 2d, forming the first semiconductor layers 31a in the opening patterns in step S142 further includes forming a patterned mask layer 21a on the native substrate 10a. The patterned mask layer 21a includes first grooves 221 and second grooves 222 arranged at intervals along the first direction. The aperture L1 of the first groove is larger than the aperture L2 of the second groove. The first grooves 221 and the second grooves 222 expose part of the native substrate 10a. A first crystal seed layer 311a′ is formed in each first groove 221, second crystal seed layer 312a′ is formed in each second groove, and the first semiconductor layer 31a is grown from each first crystal seed layer 311a′ and each second crystal seed layer 312a′. Different colors are achieved by forming differentiated crystal surface shapes through varying groove widths.

In some embodiments, the grooves may be formed using the methods such as electron beam lithography, nanoimprinting, dry etching, or wet etching.

In some embodiments, the first semiconductor layer includes a pyramid shaped morphology.

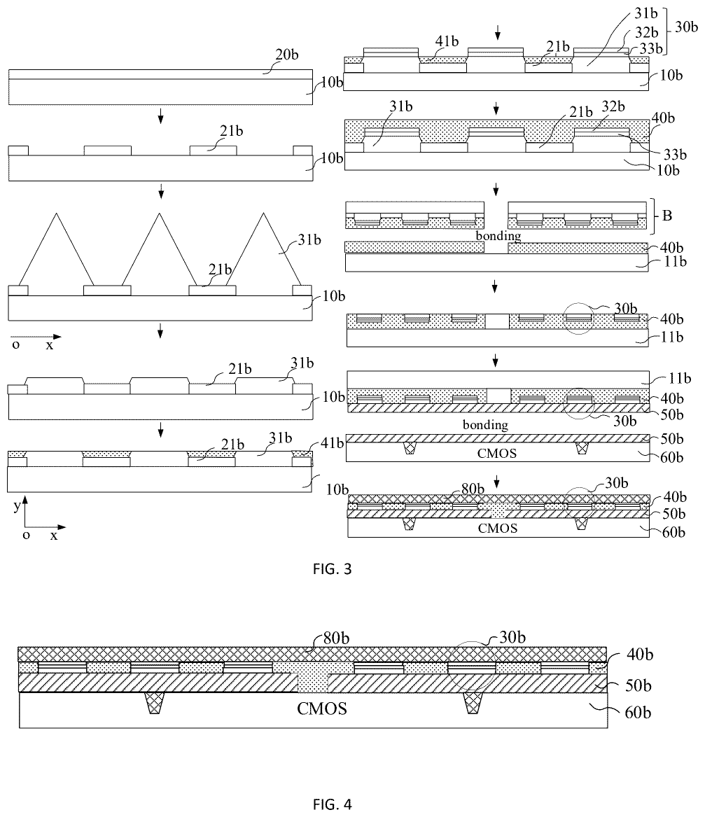

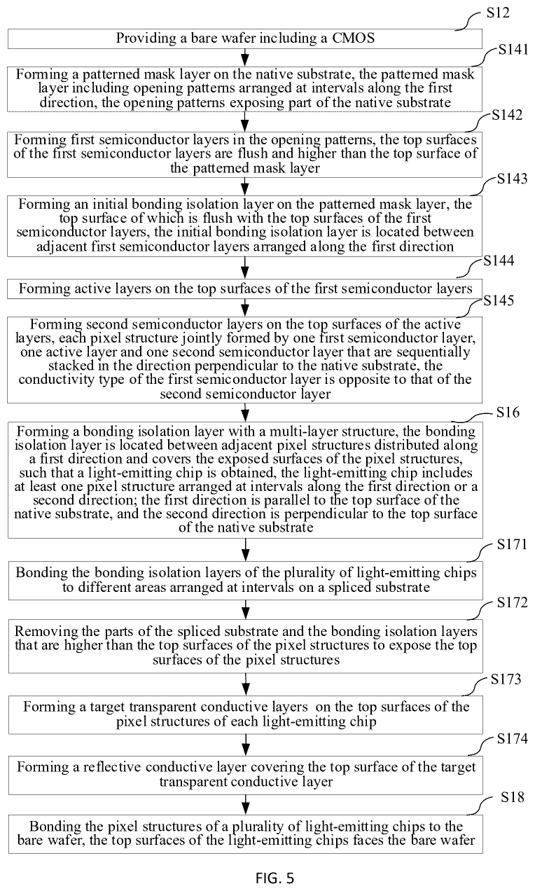

In some embodiments, referring to FIG. 3 and FIG. 4, forming the pixel structures 30b arranged at intervals on the native substrate 10b includes the following steps.

In step S141, a patterned mask layer 21b is formed on the native substrate 10b, the patterned mask layer 21b includes opening patterns arranged at intervals along the first direction, and the opening patterns expose part of the native substrate 10b.

In step S142, first semiconductor layers 31b are formed in the opening patterns, respectively, and the top surfaces of the first semiconductor layers 31b are flush and higher than the top surface of the patterned mask layer 21b.

In step S143, an initial bonding isolation layer 41b is formed on the patterned mask layer 21b, and the top surface of the initial bonding isolation layer 41b is flush with the top surfaces of the first semiconductor layers 31b. The initial bonding isolation layer 41b is located between adjacent first semiconductor layers 31b that are arranged along the first direction.

In step S144, active layers 33b are formed on the top surfaces of the first semiconductor layers 31b, respectively.

In step S145, second semiconductor layers 32b are formed on the top surfaces of the active layers 33b, respectively. Each pixel structure 30b is jointly formed by one first semiconductor layer 31b, one active layer 33b and one second semiconductor layer 32b that are sequentially stacked in the direction perpendicular to the native substrate 10b. The conductivity type of the first semiconductor layer 31b is opposite to that of the second semiconductor layer 32b.

In some embodiments, with continued reference to FIG. 3 and FIG. 4, forming the patterned mask layer 21b on the native substrate 10b in step S141 includes the following steps.

In step S1411, a mask layer 20b is formed on the top surface of the native substrate 10b.

In step S1412, a patterned photoresist layer is formed on the top surface of the mask layer 20b.

In step S1413, the mask layer 20b is etched by using the patterned photoresist layer as a mask to obtain the patterned mask layer 21b, and the remaining part of the patterned photoresist layer is removed.

As an example, with continued reference to FIG. 3 and FIG. 4, forming the patterned photoresist layer (not shown in the figures) on the top surface of the mask layer 20b in step S1412 includes forming a photoresist layer on the top surface of the mask layer 20b, and obtaining the patterned photoresist layer through a series of processes such as exposure, development, etc. The patterned photoresist layer includes an opening pattern configured to define parameters such as the position and shape of the mask layer 20b. The photoresist may be a positive photoresist or a negative photoresist. The development method may be positive development or negative development.

As an example, with continued reference to FIG. 3 and FIG. 4, in step S1413, the mask layer 20b is etched by wet etching and/or dry etching. For example, the mask layer 20b may be etched using a plasma etching process. Plasma etching refers to a process that utilizes high-frequency glow discharge reactions to activate the reaction gases into active particles, such as atoms or free radicals, and these active particles diffuse to the part to be etched and react with the material to be etched, forming volatile products that are removed to achieve the etching. The etching gas may include one or more of the following: CL₂, NF₃, CF₃, HF, CHF₄, etc. Therefore, the etching rate is increased.

In some embodiments, with continued reference to FIG. 3 and FIG. 4, bonding the pixel structures 30b of a plurality of light-emitting chips B to the bare wafer 60b in step S18 includes the following steps.

In step S181, a conductive bonding layer 50b is formed on the top surface of the bare wafer 60b.

In step S182, the plurality of light-emitting chips B are bonded to corresponding positions on the conductive bonding layer 60b, with the top surfaces of the light-emitting chips B facing the bare wafer 60b.

In some embodiments, with continued reference to FIG. 3 and FIG. 4, after bonding the plurality of light-emitting chips B to the conductive bonding layer 60b in step S182, the method also includes a step S183.

In step S183, the substrate located on the sides of the pixel structures 30b away from the bare wafer along the direction perpendicular to the bare wafer 60b is removed. The substrate includes a spliced substrate 11b or the native substrate 10b. A common electrode 80b, which is electrically connected to at least one light-emitting chip, is formed on the top surfaces of the plurality of light-emitting chips B.

As an example, with continued reference to FIG. 3 and FIG. 4, in the above method for manufacturing a pixel array, the initial bonding isolation layer 41b is formed on the patterned mask layer 21b, and the top surface of the initial bonding isolation layer 41b is flush with the top surfaces of the first semiconductor layers 31b. Each pixel structure 30b is jointly formed by one first semiconductor layer 31b, one active layer 33b, and one second semiconductor layer 32b sequentially stacked in the direction of the native substrate 10b, thereby forming the light-emitting chip B. The light-emitting chip B includes at least one pixel structure 30b arranged at intervals along the first direction or the second direction. The pixel structures 30b of a plurality of light-emitting chips B are bonded to the CMOS bare wafer 60b, with the top surfaces of the light-emitting chips B facing the bare wafer 60b, forming a pixel array. The light-emitting chips with required performance can be optimally selected, and a patterning process is performed on the pixel arrays on the substrates of various sizes, optimizing the light pattern of the pixel structure, preventing crosstalk between the various layers of the chip, reducing the difficulty of bonding, and improving the manufacturing yield and quality of compound semiconductor chips. In the related process, a CMOS substrate and a compound semiconductor epitaxial wafer are bonded together, and the compound semiconductor dies are bonded to the CMOS substrate to achieve functional control. The yield problem of the single CMOS bare wafer cannot be avoided, and defective products (i.e., defective dies) may be randomly distributed in different positions of the CMOS, resulting in yield loss during conventional bonding and waste of compound semiconductor epitaxy. In the method for manufacturing a pixel array provided in the embodiments of the present disclosure, an initial bonding isolation layer is formed on the patterned mask layer, and the top surface of the initial bonding isolation layer is flush with the top surfaces of the first semiconductor layers. Each pixel structure is formed by the sequentially formed first semiconductor layer, active layer, and second semiconductor layer, obtaining a light-emitting chip including at least one pixel structure arranged at intervals along the first direction or the second direction. The light-emitting chips with required performance are optimally selected based on the location of the defective die of the CMOS, and a patterning process is performed on the pixel arrays on the substrates of various sizes, optimizing the light pattern of the pixel structure, preventing crosstalk between the various layers of the chip, reducing the difficulty of bonding, and improving the manufacturing yield and quality of compound semiconductor chips.

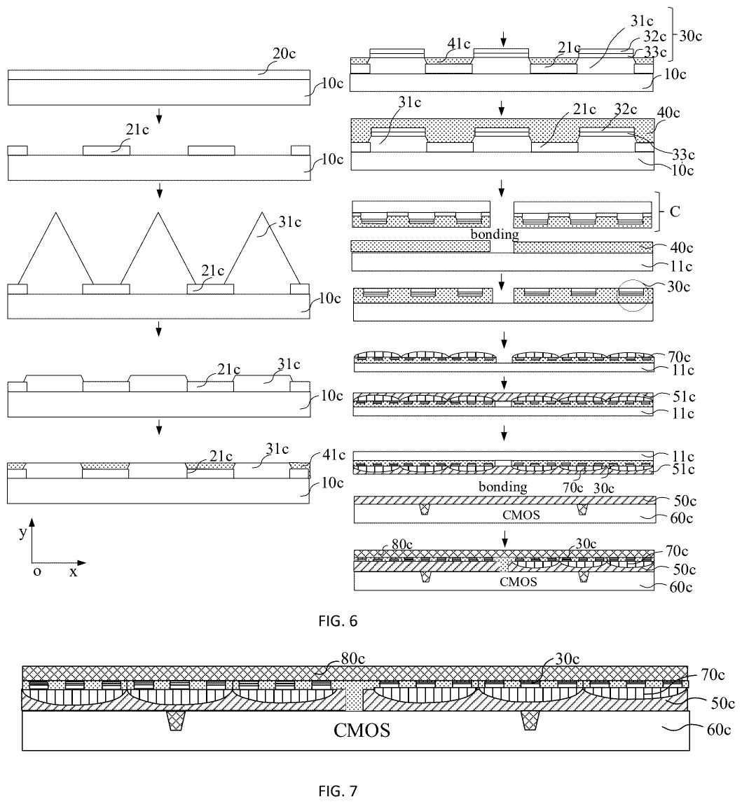

In some embodiments, referring to FIGS. 5 to 7, after forming the initial bonding isolation layer 41c and the bonding isolation layer 40c in step S16, and before bonding the pixel structures 30c of the plurality of light-emitting chips C to the bare wafer 60c in step 18, the method also includes the following steps.

In step S171, the bonding isolation layers 40c of the plurality of light-emitting chips C are bonded to different areas arranged at intervals on a spliced substrate 11c.

In step S172, the parts of the spliced substrate 11c and the bonding isolation layers 40c that are higher than the top surfaces of the pixel structures 30c are removed to expose the top surfaces of the pixel structures 30c.

In step S173, a target transparent conductive layers 70c is formed on the top surfaces of the pixel structures 30c of each light-emitting chip C.

In step S174, a reflective conductive layer 51c covering the top surface of the target transparent conductive layer 70c is formed.

In some embodiments, with continued reference to FIGS. 5 to 7, forming a patterned mask layer 21c on the native substrate 10c includes the following steps.

In step S1411, a mask layer 20c is formed on the top surface of the native substrate 10c.

In step S1412, a patterned photoresist layer is formed on the top surface of the mask layer 20c.

In step S1413, the mask layer 20c is etched by using the patterned photoresist layer as a mask to obtain the patterned mask layer 21c, and the remaining part of the patterned photoresist layer is removed.

As an example, with continued reference to FIGS. 5 to 7, forming the patterned photoresist layer (not shown in the figures) on the top surface of the mask layer 20c in step S1412 includes forming a photoresist layer on the top surface of the mask layer 20c, and obtaining the patterned photoresist layer through a series of processes such as exposure, development, etc. The patterned photoresist layer includes an opening pattern configured to define parameters such as the position and shape of the mask layer. The photoresist may be a positive photoresist or a negative photoresist. The development method may be positive development or negative development.

As an example, with continued reference to FIGS. 5 to 7, in step S1413, the mask layer 20c is etched by wet etching and/or dry etching. For example, the mask layer 20c may be etched using a plasma etching process. Plasma etching refers to a process that utilizes high-frequency glow discharge reactions to activate reactive gases into active particles, such as atoms or free radicals, and these active particles diffuse to the parts to be etched and react with the material to be etched, and form volatile products that are removed to achieve the etching. The etching gas may include one or more of the following: CL₂, NF₃, CF₃, HF, CHF₄, etc. Therefore, the etching rate is increased.

In some embodiments, with continued reference to FIGS. 5 to 7, bonding the pixel structures 30c of a plurality of light-emitting chips C to the bare wafer 60c in step S18 includes the following steps.

In step S181, a conductive bonding layer 50c is formed on the top surface of the wafer 60c.

In step S182, the plurality of light-emitting chips C are bonded to corresponding positions on the conductive bonding layer 50c, with the top surfaces of the light-emitting chips C facing the bare wafer 60c.

In some embodiments, with continued reference to FIGS. 5 to 7, after bonding the plurality of light-emitting chips C to the conductive bonding layer 50c in step S182, the method also includes a step S183.

In step S183, the substrate located on the sides of the pixel structures 30c away from the bare wafer 60c along the direction perpendicular to the bare wafer 60c is removed. The substrate includes the spliced substrate 11c or the native substrate 10c.

As an example, with continued reference to FIGS. 5 to 7, in the above method for manufacturing a pixel array, the initial bonding isolation layer 41c is formed on the patterned mask layer 21c, and the top surface of the initial bonding isolation layer 1c is flush with the top surfaces of the first semiconductor layers 31c. Each pixel structure 30c is jointly formed by one first semiconductor layer 31c, one active layer 33c, and one second semiconductor layer 32c that are sequentially stacked in the direction of the native substrate 10c, thereby forming the light-emitting chip C. The light-emitting chip C includes at least one pixel structure 30c arranged at intervals along the first direction or the second direction. The target transparent conductive layer 70c is formed on the top surfaces of the pixel structures of each light-emitting chip, and then the pixel structures 30c of the plurality of light-emitting chips Care bonded to the CMOS bare wafer 60c, with the top surfaces of the light-emitting chips C facing the bare wafer 60c, forming a pixel array. The light-emitting chips with the required performance can be optimally selected, and a patterning process is performed on the pixel arrays on the substrates of various sizes, optimizing the light extraction of the structure, optimizing the light pattern of the pixel structure, preventing crosstalk between the various layers of the chip, reducing the difficulty of bonding, and improving the manufacturing yield and quality of compound semiconductor chips. In the related process, a CMOS substrate and a compound semiconductor epitaxial wafer are bonded together, and the compound semiconductor dies are bonded to the CMOS substrate to achieve functional control. The yield problem of the single CMOS bare wafer cannot be avoided, and defective products (i.e., defective dies) may be randomly distributed in different positions of the CMOS, resulting in yield loss during conventional bonding and waste of compound semiconductor epitaxy. In the method for manufacturing a pixel array provided in the embodiments of the present disclosure, an initial bonding isolation layer is formed on the patterned mask layer, and the top surface of the initial bonding isolation layer is flush with the top surfaces of the first semiconductor layers. Each pixel structure is jointly formed by the sequentially formed first semiconductor layer, active layer, and second semiconductor layer, thereby obtaining a light-emitting chip including at least one pixel structure arranged at intervals along the first direction or the second direction. A target transparent conductive layer is formed on the top surfaces of the pixel structures of each light-emitting chip. The light-emitting chips with required performance are optimally selected based on the location of the defective die of the CMOS, and a patterning process is performed on the pixel arrays on the substrates of various sizes, optimizing the light extraction of the structure, optimizing the light pattern of the pixel structure, preventing crosstalk between the various layers of the chip, reducing the difficulty of bonding, and improving the manufacturing yield and quality of compound semiconductor chips.

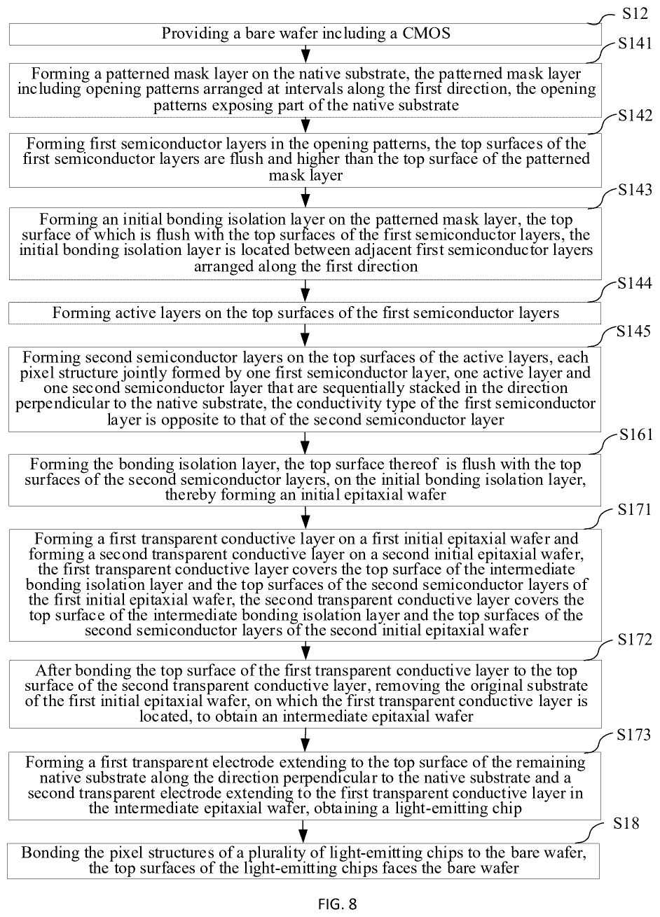

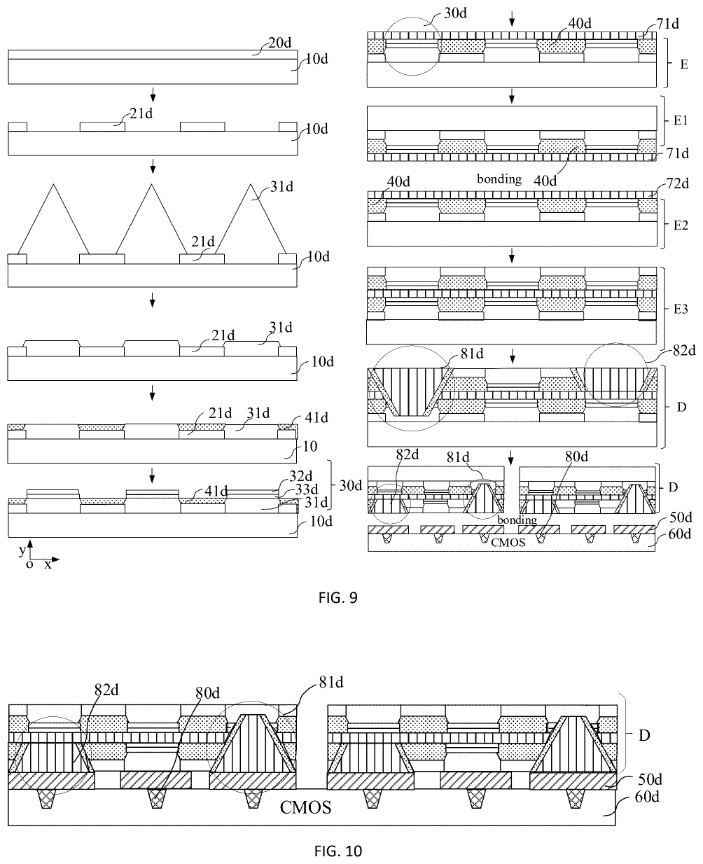

In some embodiments, referring to FIGS. 8-10, forming the pixel structures 30d arranged at intervals on the native substrate 10d in step S14 includes the following steps.

In step S141, a patterned mask layer 21d is formed on the native substrate 10d, the patterned mask layer 21d includes opening patterns arranged at intervals along the first direction, and the opening patterns expose part of the native substrate 10d.

In step S142, first semiconductor layers 31d are formed in the opening patterns, respectively, and the top surfaces of the first semiconductor layers 31d are flush and higher than the top surface of the patterned mask layer 21d.

In step S143, an initial bonding isolation layer 41d is formed on the patterned mask layer 21d, and the top surface of the initial bonding isolation layer 41d is flush with the top surfaces of the first semiconductor layers 31d. The initial bonding isolation layer 41d is located between adjacent first semiconductor layers 31d that are arranged along the first direction.

In step S144, active layers 33d are formed on the top surfaces of the first semiconductor layers 31d, respectively.

Step S145: second semiconductor layers 31d are formed on the top surfaces of the active layers 33d, respectively. Each pixel structure 30d is jointly formed by one first semiconductor layer 31d, one active layer 33d, and one second semiconductor layer 32d that are sequentially stacked in the direction perpendicular to the native substrate 10d. The conductivity type of the first semiconductor layer 31d is opposite to that of the second semiconductor layer 32d.

In some embodiments, with continued reference to FIGS. 8 to 10, forming the patterned mask layer 21d on the native substrate 10d includes the following steps.

In step S1411, a mask layer 20d is formed on the top surface of the native substrate 10d.

In step S1412, a patterned photoresist layer is formed on the top surface of the mask layer 20d.

In step S1413, the mask layer 20d is etched by using the patterned photoresist layer as a mask to obtain the patterned mask layer 21d, and the remaining part of the patterned photoresist layer is removed.

As an example, with continued reference to FIGS. 8 to 10, forming the patterned photoresist layer (not shown in the figures) on the top surface of the mask layer 20d in step S1412 includes forming a photoresist layer on the top surface of the mask layer 20d, and obtaining the patterned photoresist layer through a series of processes such as exposure, development, etc. The patterned photoresist layer includes an opening pattern configured to define parameters such as the position and shape of the mask layer. The photoresist may be a positive photoresist or a negative photoresist. The development method may be positive development or negative development.

As an example, with continued reference to FIGS. 8 to 10, in step S1413, the mask layer 20d is etched by wet etching and/or dry etching. For example, the mask layer 20d may be etched using a plasma etching process. Plasma etching refers to a process that utilizes high-frequency glow discharge reactions to activate reaction gases into active particles, such as atoms or free radicals, and these active particles diffuse to the part to be etched and react with the material to be etched, and form volatile products that are removed to achieve the etching. The etching gas may include one or more of the following: CL₂, NF₃, CF₃, HF, CHF₄, etc. Therefore, the etching rate is increased.

In some embodiments, with continued reference to FIGS. 8 to 10, forming the bonding isolation layer 40d in step S16 further includes a step S161.

In step S161, the bonding isolation layer 40d, the top surface thereof is flush with the top surfaces of the second semiconductor layers, is formed on the initial bonding isolation layer 41d, forming an initial epitaxial wafer E. It can be understood that a plurality of initial epitaxial wafers E can be formed.

After forming the bonding isolation layer 40d in step S16, the method further includes the following steps.

In step S171, a plurality of initial epitaxial wafers including a first initial epitaxial wafer and a second initial epitaxial wafer are provided, a first transparent conductive layer 71d is formed on the first initial epitaxial wafer E1, and a second transparent conductive layer 72d is formed on the second initial epitaxial wafer E2. The first transparent conductive layer 71d covers the top surface of the intermediate bonding isolation layer 40d and the top surfaces of the second semiconductor layers 32d of the first initial epitaxial wafer E1. The second transparent conductive layer 72d covers the top surface of the intermediate bonding isolation layer 40d and the top surfaces of the second semiconductor layers 32d of the second initial epitaxial wafer E2.

In step S172, after bonding the top surface of the first transparent conductive layer 71d to the top surface of the second transparent conductive layer 72d, the original substrate 10d of the first initial epitaxial wafer E1, on which the first transparent conductive layer 71d is located, is removed to obtain an intermediate epitaxial wafer E3.

In step S173, a first transparent electrode 81d extending to the top surface of the remaining native substrate 10d along the direction perpendicular to the native substrate 10d and a second transparent electrode 82d extending to the first transparent conductive layer 71d are formed in the intermediate epitaxial wafer E3, obtaining a light-emitting chip D.

In some embodiments, with continued reference to FIGS. 8 to 10, bonding the pixel structures 30d of a plurality of light-emitting chips D to the bare wafer 60d in step S18 includes the following steps.

In step S181, a conductive bonding layer 50d is formed on the top surface of the bare wafer 60d.

In step S182, the plurality of light-emitting chips D are bonded to corresponding positions on the conductive bonding layer 50d, with the top surfaces of the light-emitting chips D facing the bare wafer 60d.

In some embodiments, with continued reference to FIGS. 8 to 10, after bonding the plurality of light-emitting chips D to the conductive bonding layer 50d in step S182, the method also includes a step S183.

In step S183, the substrate located on the sides of the pixel structures 30d away from the bare wafer 60d along the direction perpendicular to the bare wafer 60d is removed. The substrate includes the native substrate 10d. A common electrode 80d electrically connected to at least one light-emitting chip is formed inside the bare wafer 60d.

As an example, with continued reference to FIGS. 8-10, in the above method for manufacturing a pixel array, the initial bonding isolation layer 41d is formed on the patterned mask layer 21d, and the top surface of the initial bonding isolation layer 41 is flush with the top surfaces of the first semiconductor layers 31d. Each pixel structure 30d is jointly formed by one first semiconductor layer 31d, one active layer 33d and one second semiconductor layer 32d that are sequentially stacked in the direction of the original substrate 10d. The bonding isolation layer 40d is formed on the initial bonding isolation layer 41d, and the top surface of the bonding isolation layer 40d is flush with the top surfaces of the second semiconductor layers 32d. The plurality of initial epitaxial wafers E are formed. The first transparent conductive layer 71d is formed on one initial epitaxial wafer E1, and the second transparent conductive layer 72d is formed on another initial epitaxial wafer E2. After the top surface of the first transparent conductive layer 71d is bonded to the top surface of the second transparent conductive layer 72d, the intermediate epitaxial wafer E3 is obtained. The first transparent electrode 81d and the second transparent electrode 82d are formed in the intermediate epitaxial wafer E3, obtaining the light-emitting chip D. Then, the pixel structures 30d, the first transparent electrodes 81d and the second transparent electrodes 82d of a plurality of light-emitting chips D are bonded to the CMOS bare wafer 60d, with the top surfaces of the light-emitting chips D facing the bare wafer 60d, forming a pixel array. The light-emitting chips with the required performance can be optimally selected, and a patterning process is performed on the pixel arrays on the substrates of various sizes, optimizing the light extraction of the structure, optimizing the light pattern of the pixel structure, preventing crosstalk between the various layers of the chip, reducing the difficulty of bonding, and improving the manufacturing yield and quality of compound semiconductor chips. In the related process, a CMOS substrate and a compound semiconductor epitaxial wafer are bonded together, and the compound semiconductor dies are bonded to the CMOS substrate to achieve functional control. The yield problem of the single CMOS bare wafer cannot be avoided, and the defective products (i.e., defective dies) may be randomly distributed in different positions of the CMOS, resulting in yield loss during conventional bonding and waste of compound semiconductor epitaxy. In the method for manufacturing a pixel array provided in the embodiment of the present disclosure, an initial bonding isolation layer is formed on the patterned mask layer, and the top surface of the initial bonding isolation layer is flush with the top surfaces of the first semiconductor layers. Each pixel structure is jointly formed by the sequentially formed first semiconductor layer, active layer and second semiconductor layer. A bonding isolation layer is formed on an initial bonding isolation layer, and the top surface of the bonding isolation layer is flush with the top surfaces of the second semiconductor layers. A plurality of initial epitaxial wafers are formed. A first transparent conductive layer is formed on one initial epitaxial wafer, and a second transparent conductive layer is formed on another initial epitaxial wafer. After the top surface of the first transparent conductive layer is bonded to the top surface of the second transparent conductive layer, an intermediate epitaxial wafer is obtained. A first transparent electrode and a second transparent electrode are formed in the intermediate epitaxial wafer, obtaining a light-emitting chip. Then, the pixel structures, the first transparent electrodes and the second transparent electrodes of a plurality of light-emitting chips are bonded to a CMOS bare wafer. The light-emitting chips with the required performance are optimally selected based on the location of the defective die of the CMOS, and a patterning process is performed on the pixel arrays on the substrates of various sizes. Via holes in the pixel array structure have a reflective effect, optimizing the light extraction of the structure, optimizing the light pattern of the pixel structure, preventing crosstalk between various layers of the chip, reducing the difficulty of bonding, and improving the manufacturing yield and quality of compound semiconductor chips.

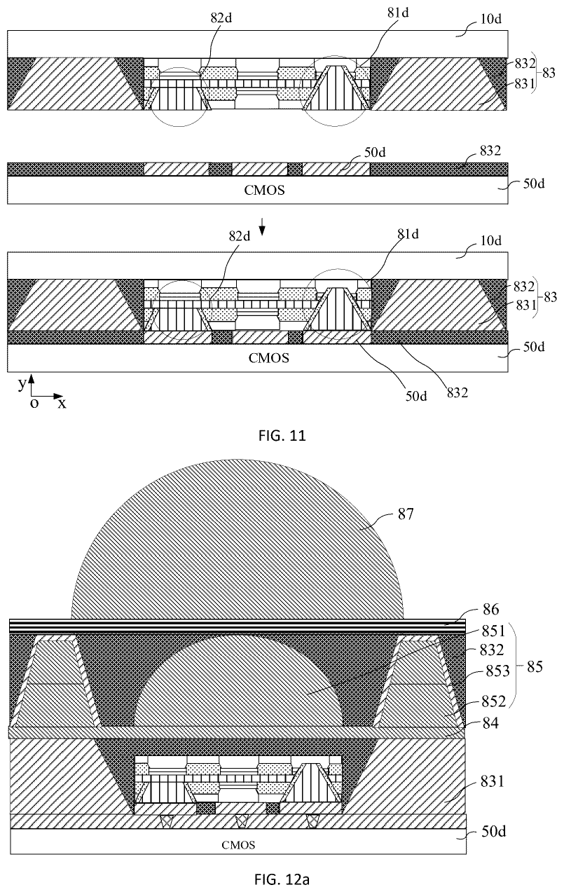

In some embodiments, referring to FIG. 11, before bonding the pixel structures 30d of the plurality of light-emitting chips D to the bare wafer 60d in step S18, the method also includes forming a reflective cup structure 83 on both the left and right sides of the light-emitting chip D on the native substrate 10d. The reflective cup structure 83 includes a reflective medium layer 831 and transparent medium layers 832 located on the left and right sides of the reflective medium layer 831.

Specifically, the reflective medium layer 831 in the reflective cup structure 83 includes gold, silver, or aluminum. The reflective medium layer may also be a core-shell structure, with the surface layer being a reflective medium and the filling core being other medium, such as SiOx.

In some embodiments, with continued reference to FIG. 11, bonding the pixel structures 30d of the light-emitting chips D to the bare wafer 60d in step S18 includes the following steps.

In step S181, conductive bonding layers 50d and transparent medium layers 832 are formed on the top surface of the bare wafer 60d.

In step S182, the plurality of light-emitting chips D are bonded to corresponding positions on the conductive bonding layers 50d and the transparent medium layers 832, with the top surfaces of the light-emitting chips D facing the bare wafer 60d.

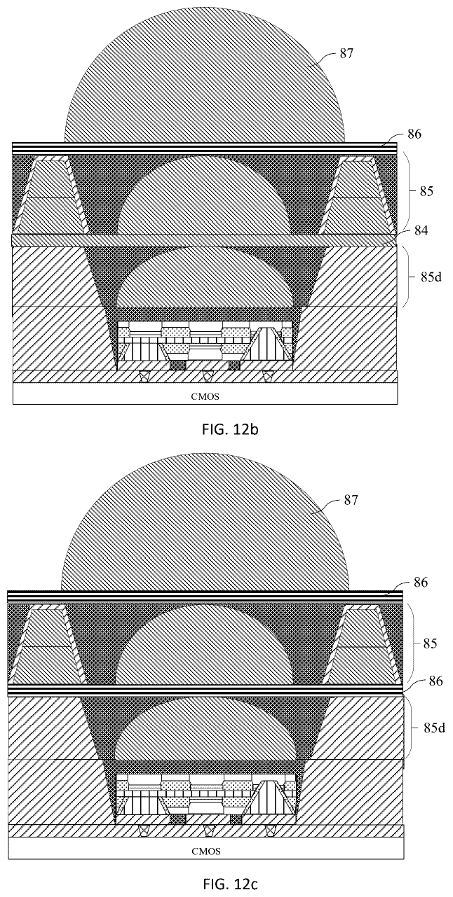

In some embodiments, referring to FIG. 12a, after bonding the pixel structures 30d of the plurality of light-emitting chips D to the bare wafer 60d to form the pixel array in step S18, the method further includes the following steps.

In step S19, a blocking layer 84 is formed on the top surface of the pixel array.

In step S20, a reflector layer 85 is formed on the top surface of the blocking layer 84.

In step S21, a Bragg reflector layer 86 is formed on the top surface of the reflector layer 85.

In step S22, a second reflector 87 is formed on the top surface of the Bragg reflector layer 86.

In some embodiments, with continued reference to FIG. 12a, the reflector layer 85 includes a first sub-reflector 851, the transparent medium layer 832, and reflective structures located on the left and right sides of the first sub-reflector 851. Each reflective structure includes a second sub-reflector 852 and a first reflective layer 853 surrounding the second sub-reflector 852. The transparent medium layer 832 fills the gap between the first sub-reflector 851 and the reflective structures.

In some embodiments, referring to FIG. 12b, after bonding the pixel structures 30d of the plurality of light-emitting chips D to the bare wafer 60d to form the pixel array in step S18, the method also includes the following steps.

In step S19, a first reflector layer 85d is formed on the top surface of the pixel array.

In step S20, a blocking layer 84 is formed on the top surface of the first reflector layer 85d.

In step S21, a reflector layer 85 is formed on the top surface of the blocking layer 84.

In step S22, a Bragg reflector layer 86 is formed on the top surface of the reflector layer 85;

In step S23, a second reflector 87 is formed on the top surface of the Bragg reflector layer 86.

In some embodiments, the first reflector layer 85d includes a reflector, a reflective medium layer located on both sides of the reflector, and a transparent medium layer filling the gap between the reflector and the reflective medium layer.

In some embodiments, referring to FIG. 12c, forming the blocking layer 84 on the top surface of the first reflector layer 85d in step S20 may also be:

Step S20, forming a Bragg reflector layer 86 on the top surface of the first reflector layer.

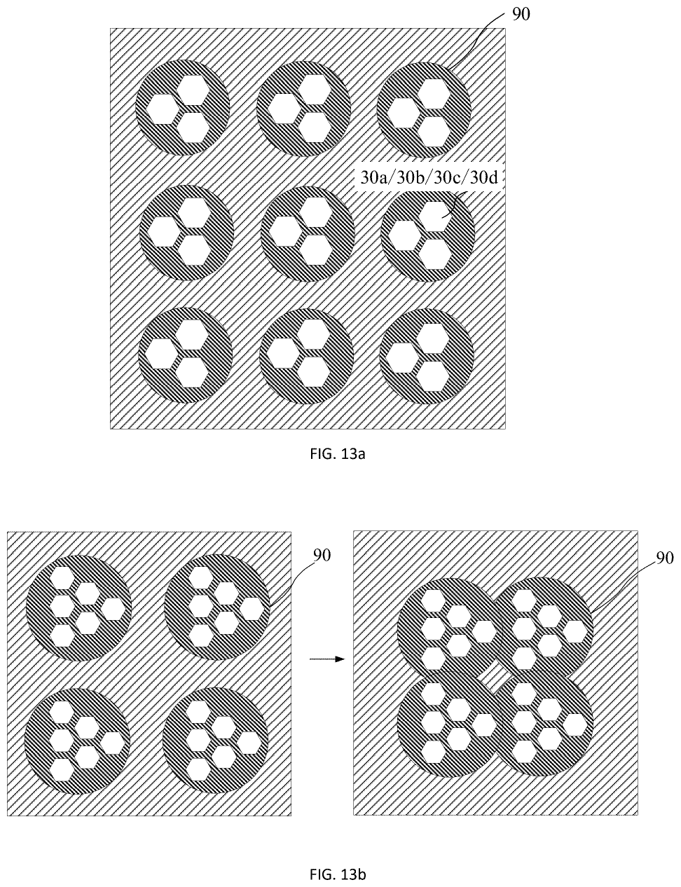

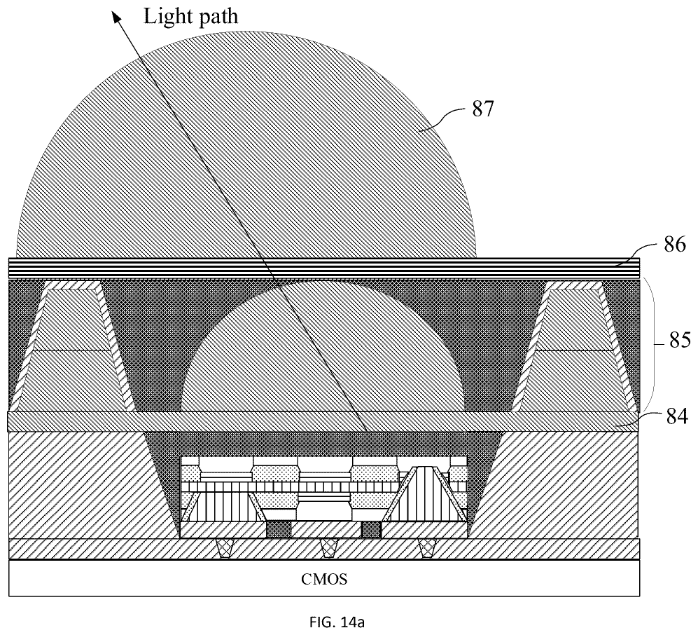

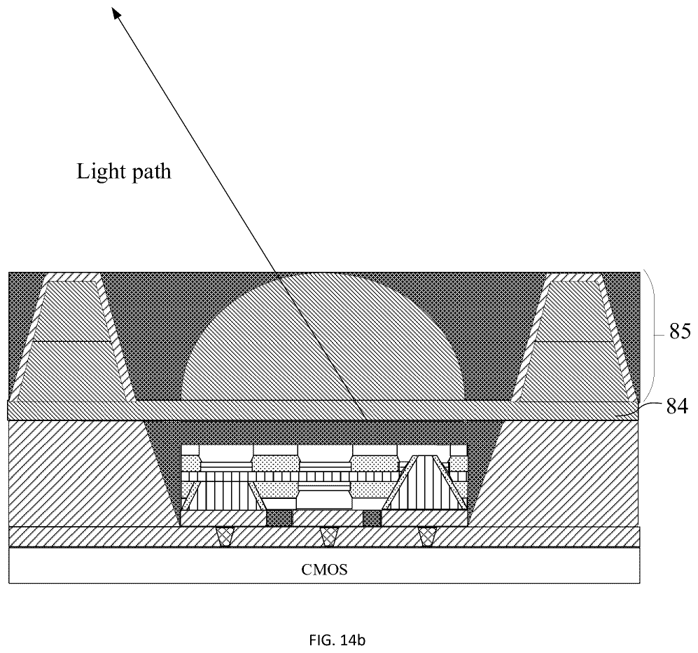

In some embodiments, referring to FIG. 13a, a pixel unit 90 includes at least one pixel group, each pixel group includes at least one pixel layer (not shown in the figures), and each pixel layer includes at least one pixel structure 30a/30b/30c/30d, the shape of the pixel structure 30a/30b/30c/30d may be a polygon, such as a quadrilateral, a hexagon, or an octagon.

In some embodiments, referring to FIG. 13b, a plurality of pixel units 90 can be fused to optimize the geometric center of the mixed color.

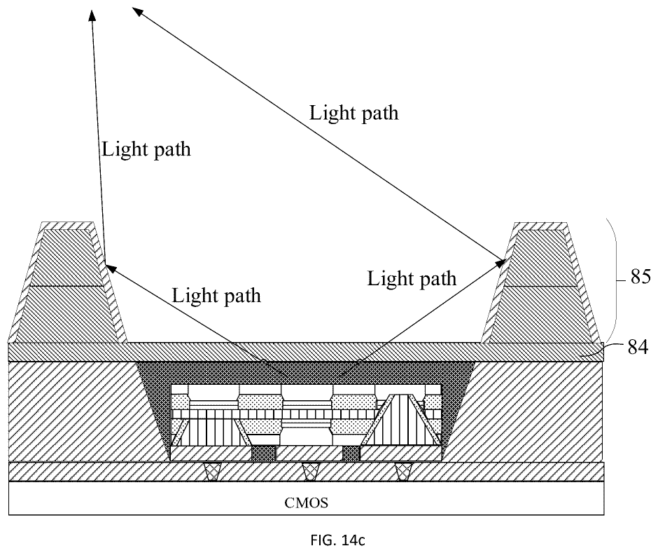

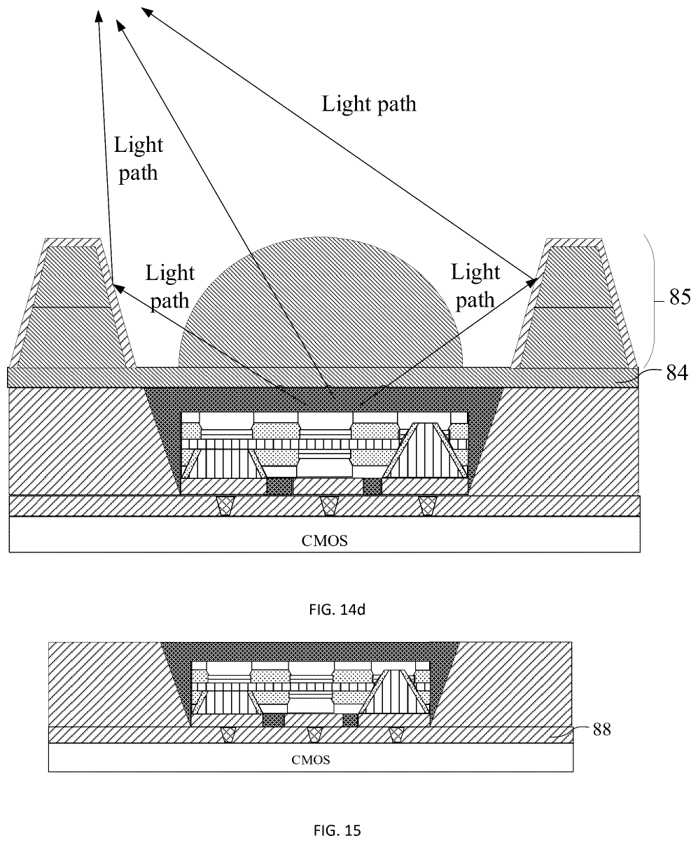

In some embodiments, referring to FIGS. 14a to 14d, by arranging the blocking layer 84, the reflector layer 85, the Bragg reflector layer 86 and the second reflector layer 87 on the reflective cup, the reflected light path is optimized and the light extraction of the pixel structure is improved. For example, the second reflector 87 may be designed off-axis, modulating the angular light pattern, adjusting the reflected light path, cooperating with the optical machine to improve efficiency, and improving the light extraction of the pixel structure. For another example, the reflective cup may be designed off-axis, modulating the angular light pattern, adjusting the reflected light path, cooperating with the optical machine to improve efficiency, and improving the light extraction of the pixel structure.

In some embodiments, referring to FIG. 15, before bonding the pixel structures 30d of the plurality of light-emitting chips D to the bare wafer 60d in step S18 and after forming each light-emitting chip D with the reflective cup structure, a bottom reflective layer 88 is formed on the bottom surface of each light-emitting chip D, cooperating with the optical machine to improve the efficiency and improving the light extraction of the pixel structures.

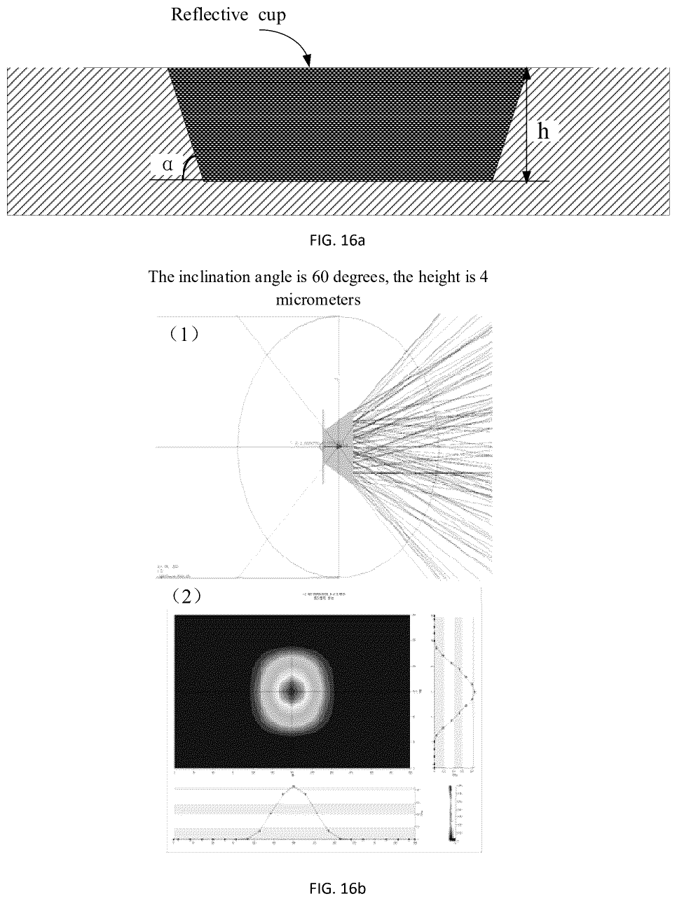

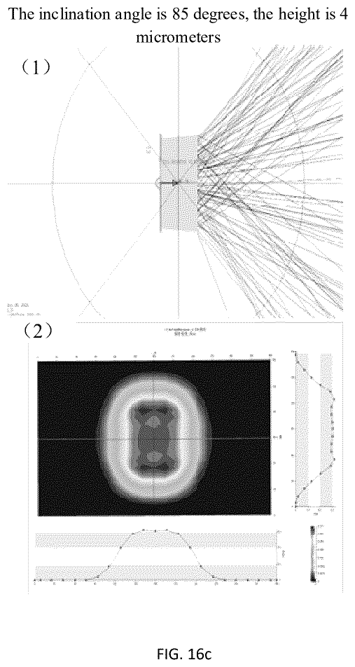

In some embodiments, referring to FIGS. 16a to 16c, the optimal inclination angle and optimal height of the reflective cup are obtained by performing simulation calculations on the reflective cup. For example, when the inclination angle α of the reflective cup is set to 60 degrees and the height h of the reflective cup is set to 4 micrometers, the reflected light path diagram of the reflective cup as shown in sub-figure (1) in FIG. 16b and the color distribution diagram as shown in sub-figure (2) in FIG. 16b are obtained. It can be seen that the color distribution of the pixel structure is concentrated when the inclination angle α of the reflective cup is 60 degrees and the height h is 4 micrometers. For another example, when the inclination angle α of the reflective cup is set to 85 degrees and the height h of the reflective cup is set to 4 micrometers, the reflected light path diagram as shown in sub-figure (1) in FIG. 16c and the color distribution diagram as shown in sub-figure (2) in FIG. 16c are obtained. It can be seen that the color distribution of the pixel structure is wide when the inclination angle α of the reflective cup is 85 degrees and the height h is 4 micrometers. The impact of different inclination angles α on the reflected light path and color distribution under the same height h of the reflective cup is analyzed through the reflected light path diagram and color distribution diagram of the reflective cup obtained by simulation.

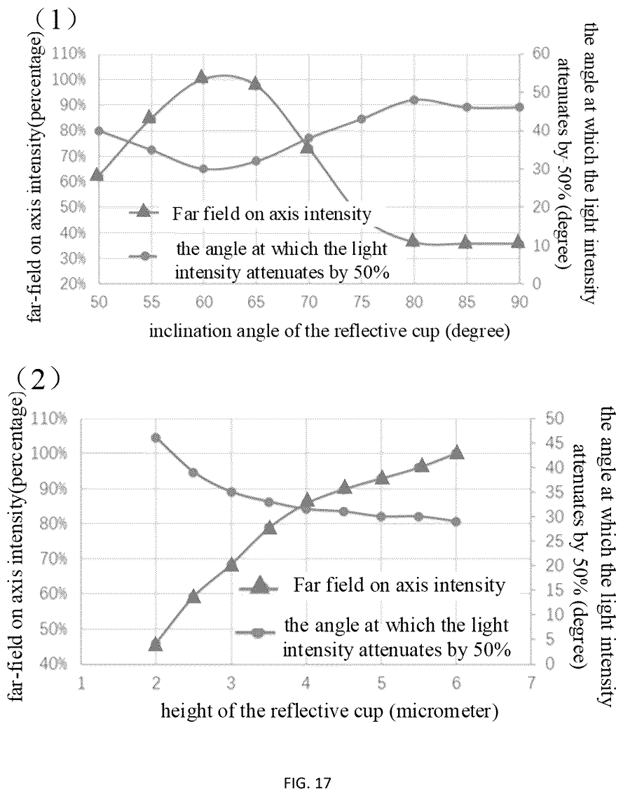

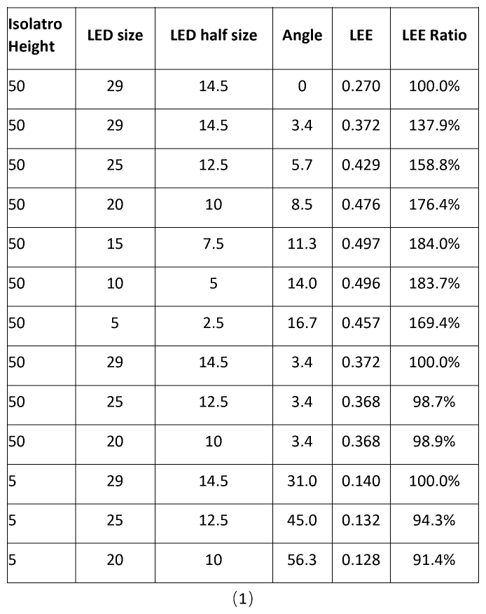

In some embodiments, please refer to FIG. 17. As shown in sub-figure (1) of FIG. 17, the optimal inclination angle is determined to be 55 degrees to 65 degrees based on the inclination angle of the reflective cup, the far-field on-axis intensity, and the angle at which the light intensity attenuates by 50%. As shown in sub-figure (2) of FIG. 17, based on the height of the reflective cup, the far-field on-axis intensity, and the angle at which the light intensity attenuates by 50%, it is determined that the optimal height can be selected as the maximum value according to the actual process ability to enhance the light extraction of the pixel structure.

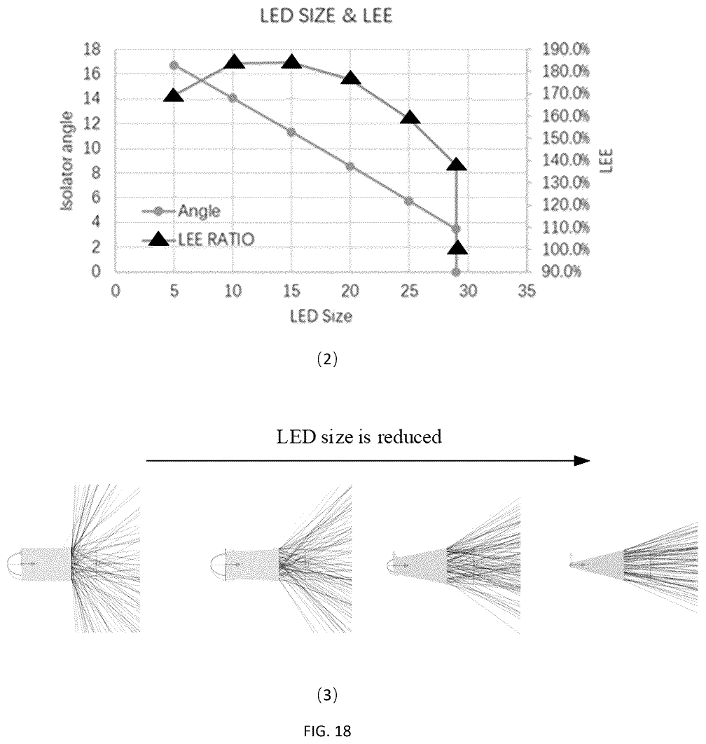

In some embodiments, referring to FIG. 18, a relationship between the taper angle of the second sub-reflector 852, the LED (light source) size (i.e., the size of the top surface of the second sub-reflector 852 as shown in FIG. 12a), and the light extraction efficiency (LEE) can be obtained by the simulation of the second sub-reflector 852. It can be concluded that the light extraction efficiency is optimal when the LED size is equal to 50% of the pitch. The LED that is too large or too small will produce multiple reflections. When the taper angle is fixed, simply reducing the LED size has little effect on the light extraction efficiency.

It should be noted that in some embodiments of the present disclosure, the patterned mask layer 21a/21b/21c/21d includes film structure such as SiOx, SiNx, etc., or a surface coating TiOx, etc. Depending on the integrity of the epitaxially grown crystal and the growth speed, the desired epitaxial layer is formed in the opening area of the patterned mask layer 21a/21b/21c/21d.

As an example, referring to FIG. 2a to FIG. 11, the bonding isolation layer 40a/40b/40c/40d or the initial bonding isolation layer 41b/41c/41d covering the exposed surface of the pixel structure 30a/30b/30c/30d refers to covering the side surface of the upper end portion of the first semiconductor layer 31a/31b/31c/31d, the side surface of the active layer 33a/33b/33c/33d, and the side surface and top surface of the second semiconductor layer 32a/32b/32c/32d.

As an example, referring to FIG. 2a to FIG. 11, the direction perpendicular to the native substrate 10a/10b/10c/10d includes the direction perpendicular to the bottom surface of the native substrate 10a/10b/10c/10d. The direction perpendicular to the bare wafer 60a/60b/60c/60d includes the direction perpendicular to the bottom surface of bare wafer 60a/60b/60c/60d.

It should be noted that in some embodiments, the transparent conductive layer has the following characteristics: when light passes through the transparent conductive layer, if the direction of the light is not changed (i.e., the light can pass through in parallel), the transparent conductive layer can not only transmit light, but also transmit image. Transparency refers to the property of a material that allows light to pass through, which can be represented by transmittance, i.e., the ratio of the intensity of light passing through the material to the intensity of incident light. A material with good transparency may have a transmittance of more than 90%. The transmittance of an opaque material is zero. In addition, materials with low transmittance are also referred to as translucent materials.

In some embodiments, another aspect of the present disclosure provides a pixel array manufactured by any of the above methods for manufacturing a pixel array.

It should be understood that although various steps in the flowcharts of FIGS. 1, 5 and 8 are sequentially shown by the indications of the arrows, these steps are not necessarily executed in the order indicated by arrows. Unless explicitly stated herein, the execution of these steps is not strictly limited to the order, and these steps may be executed in other orders. Moreover, although at least a part of the steps in FIGS. 1, 5 and 8 may include multiple steps or stages, these steps or stages are not necessarily executed at the same time, but may be executed at different times. The execution order of the steps or stages is not necessarily sequential, but may be performed in turn or alternately with other steps or at least part of the steps or stages in other steps.

It should be noted that the above embodiments are merely for illustrative purposes and are not meant to limit the present disclosure.

The embodiments in the present description are described in a progressive manner. Each embodiment focuses on the differences from other embodiments, and the same and similar parts between the various embodiments can be referred to each other.

In this specification of the present disclosure, reference to the description of the terms “some embodiments”, “other embodiments” and the like are intended to refer to a specific feature, configuration, material, or characteristic described in connection with that embodiment or example included in at least one embodiment or example of the present disclosure. In this specification, schematic descriptions of the above terms do not necessarily refer to the same embodiment or example.

The technical features in the above embodiments may be randomly combined. For brevity, not all possible combinations of the technical features in the above embodiments are described. However, all the combinations of the technical features should be considered to be included within the scope of the present disclosure, as long as the combinations are not contradictory.

The above-mentioned embodiments only illustrate several embodiments of the present disclosure, and the descriptions of which are relatively specific and detailed, but should not be construed as limitations to the scope of the present disclosure. It should be noted that, for those skilled in the art, variations and improvements can be made without departing from the concept of the present disclosure, which all belong to the protection scope of the present disclosure. Therefore, the protection scope of the present disclosure shall be subject to the appended claims.

1. A method for manufacturing a pixel array, comprising:
providing a bare wafer comprising a complementary metal oxide semiconductor;
providing a native substrate and forming pixel structures arranged at intervals on the native substrate;
forming a bonding isolation layer with a multi-layer structure, the bonding isolation layer being located between adjacent pixel structures distributed along a first direction and covering exposed surfaces of the pixel structures to obtain a light-emitting chip, the light-emitting chip comprising at least one pixel structure arranged at intervals along the first direction or a second direction, the first direction being parallel to a top surface of the native substrate, the second direction being perpendicular to the top surface of the native substrate; and
bonding the pixel structures of a plurality of the light-emitting chips to the bare wafer, with top surfaces of the light-emitting chips facing the bare wafer.

2. The method according to claim 1, wherein the forming the pixel structures arranged at intervals on the native substrate comprises:
forming a patterned mask layer on the native substrate, the patterned mask layer comprising opening patterns arranged at intervals along the first direction, the opening patterns exposing part of the native substrate;
forming first semiconductor layers in the opening patterns, respectively, with top surfaces of the first semiconductor layers being flush and higher than a top surface of the patterned mask layer;
forming active layers covering outer surfaces of the first semiconductor layers, respectively, and arranged at intervals along the first direction; and
forming second semiconductor layers covering outer surfaces of the active layers, respectively, and arranged at intervals along the first direction, wherein each pixel structure is jointly formed by one first semiconductor layer, one active layer, and one second semiconductor layer that are sequentially stacked in a direction perpendicular to the native substrate, and a conductivity type of the first semiconductor layer is opposite to that of the second semiconductor layer.

3. The method according to claim 1, wherein the forming the pixel structures arranged at intervals on the native substrate comprises:
forming a patterned mask layer on the native substrate, the patterned mask layer comprising opening patterns arranged at intervals along the first direction, the opening patterns exposing part of the native substrate;
forming first semiconductor layers in the opening patterns, respectively, with top surfaces of the first semiconductor layers being flush and higher than a top surface of the patterned mask layer;
forming an initial bonding isolation layer on the patterned mask layer, a top surface of the initial bonding isolation layer being flush with the top surfaces of the first semiconductor layers, the initial bonding isolation layer being located between adjacent first semiconductor layers that are arranged along the first direction;
forming active layers on the top surfaces of the first semiconductor layers, respectively; and
forming second semiconductor layers on top surfaces of the active layers, respectively; wherein each pixel structure is jointly formed by one first semiconductor layer, one active layer, and one second semiconductor layer that are sequentially stacked in a direction perpendicular to the native substrate, and a conductivity type of the first semiconductor layer is opposite to that of the second semiconductor layer.

4. The method according to claim 3, after forming the bonding isolation layer and before bonding the pixel structures of the plurality of light-emitting chips to the bare wafer, further comprising:
bonding the bonding isolation layers of the plurality of the light-emitting chips to different areas arranged at intervals on a spliced substrate;
removing parts of the spliced substrate and the bonding isolation layer that are higher than top surfaces of the pixel structures to expose the top surfaces of the pixel structures;
forming a target transparent conductive layer on the top surface of the pixel structures of each light-emitting chip; and
forming a reflective conductive layer covering the top surface of the target transparent conductive layer.

5. The method according to claim 1, wherein the forming the pixel structures arranged at intervals on the native substrate comprises:
forming a patterned mask layer on the native substrate, the patterned mask layer comprising opening patterns arranged at intervals along the first direction, the opening patterns exposing parts of the native substrate;
forming first semiconductor layers in the opening patterns, with the top surfaces of the first semiconductor layers being flush and higher than a top surface of the patterned mask layer;
forming an initial bonding isolation layer on the patterned mask layer, a top surface of the initial bonding isolation layer being flush with the top surfaces of the first semiconductor layers, the initial bonding isolation layer being located between adjacent first semiconductor layers that are arranged along the first direction;
forming active layers on the top surfaces of the first semiconductor layers, respectively; and
forming second semiconductor layers on the top surfaces of the active layers, respectively, wherein each pixel structure is jointly formed by the first semiconductor layer, the active layer, and the second semiconductor layer that are sequentially stacked in a direction perpendicular to the native substrate, and a conductivity type of the first semiconductor layer is opposite to that of the second semiconductor layer.

6. The method according to claim 5, wherein the forming the bonding isolation layer further comprises:
forming a bonding isolation layer on the initial bonding isolation layer, a top surface of the bonding isolation layer being bflush with the top surfaces of the second semiconductor layers, thereby obtaining an initial epitaxial wafer; and wherein
after forming the bonding isolation layer, the method also comprises:
providing a plurality of initial epitaxial wafers comprising a first initial epitaxial wafer and a second initial epitaxial wafer;
forming a first transparent conductive layer on the first initial epitaxial wafer and forming a second transparent conductive layer on the second initial epitaxial wafer, wherein the first transparent conductive layer covers a top surface of an intermediate bonding isolation layer of the first initial epitaxial wafer and the top surfaces of the second semiconductor layers of the first initial epitaxial wafer, and the second transparent conductive layer covers a top surface of an intermediate bonding isolation layer of the second initial epitaxial wafer and the top surfaces of the second semiconductor layers of the second initial epitaxial wafer;
after a top surface of the first transparent conductive layer is bonded to a top surface of the second transparent conductive layer, removing the native substrate of the first initial epitaxial wafer on which the first transparent conductive layer is located, thereby obtaining an intermediate epitaxial wafer; and
forming a first transparent electrode extending to a top surface of the remaining native substrate along a direction perpendicular to the native substrate and a second transparent electrode extending to the first transparent conductive layer in the intermediate epitaxial wafer, thereby obtaining the light-emitting chip.

7. The method according to claim 1, wherein the bonding the pixel structures of the plurality of light-emitting chips to the bare wafer comprises:
forming a conductive bonding layer on a top surface of the bare wafer; and
bonding the plurality of light-emitting chips to corresponding positions on the conductive bonding layer, with top surfaces of the light-emitting chips facing the bare wafer.

8. The method according to claim 7, after bonding the plurality of light-emitting chips to the conductive bonding layer, further comprising:
removing a substrate located on one side of the pixel structures away from the bare wafer along a direction perpendicular to the bare wafer, the substrate comprising a spliced substrate or the native substrate; and
forming a common electrode electrically connected to at least one of the light-emitting chips.

9. The method according to claim 2, wherein the forming the patterned mask layer on the native substrate comprises:
forming a mask layer on the top surface of the native substrate;
forming a patterned photoresist layer on a top surface of the mask layer;
etching the mask layer by using the patterned photoresist layer as a mask to obtain the patterned mask layer; and
removing a remaining part of the patterned photoresist layer.

10. The method according to claim 1, wherein before bonding the pixel structures of the plurality of light-emitting chips to the bare wafer, the method further comprises:
forming a reflective cup structure on left and right sides of the light-emitting chip on the native substrate, the reflective cup structure comprising a reflective medium layer and transparent medium layers located on left and right sides of the reflective medium layer.

11. The method according to claim 10, wherein after bonding the pixel structures of the plurality of light-emitting chips to the bare wafer to form the pixel array, the method further comprises:
forming a blocking layer on a top surface of the pixel array;
forming a reflector layer on a top surface of the blocking layer;
forming a Bragg reflector layer on a top surface of the reflector layer; and
forming a second reflector on a top surface of the Bragg reflector layer.

12. The method according to claim 11, wherein the reflector layer comprises a first sub-reflector, a transparent medium layer, and reflective structures located on left and right sides of the first sub-reflector, each reflective structure comprises a second sub-reflector and a first reflective layer surrounding the second sub-reflector, and the transparent medium layer fills a gap between the first sub-reflector and the reflective structures.

13. The method according to claim 10, wherein after bonding the pixel structures of the plurality of light-emitting chips to the bare wafer to form the pixel array, the method further comprises:
forming a first reflector layer on a top surface of the pixel array;
forming a blocking layer on a top surface of the first reflector layer;
forming a reflector layer on a top surface of the blocking layer;
forming a Bragg reflector layer on a top surface of the reflector layer; and
forming a second reflector on a top surface of the Bragg reflector layer.

14. The method according to claim 13, wherein the first reflector layer comprises a reflector, a reflective medium layer located on both sides of the reflector, and a transparent medium layer filling a gap between the reflector and the reflective medium layer.

15. The method according to claim 10, wherein after bonding the pixel structures of the plurality of light-emitting chips to the bare wafer to form the pixel array, the method further comprises:
forming a first reflector layer on a top surface of the pixel array;
forming a first Bragg reflector layer on a top surface of the first reflector layer;
forming a reflector layer on a top surface of the first Bragg reflector layer;
forming a second Bragg reflector layer on a top surface of the reflector layer; and
forming a second reflector on a top surface of the second Bragg reflector layer.

16. The method according to claim 10, wherein before bonding the pixel structures of the plurality of light-emitting chips to the bare wafer and after forming each light-emitting chip with the reflective cup structure, the method further comprises:
forming a bottom reflective layer on a bottom surface of each light-emitting chip.

17. The method according to claim 10, wherein an inclination angle of the reflective cup is 55 degrees to 65 degrees.

18. A pixel array manufactured by a method for manufacturing a pixel array, the method comprising:
providing a bare wafer comprising a complementary metal oxide semiconductor;
providing a native substrate and forming pixel structures arranged at intervals on the native substrate;
forming a bonding isolation layer with a multi-layer structure, the bonding isolation layer being located between adjacent pixel structures distributed along a first direction and covering exposed surfaces of the pixel structures to obtain a light-emitting chip, the light-emitting chip comprising at least one pixel structure arranged at intervals along the first direction or a second direction, wherein the first direction is parallel to a top surface of the native substrate, and the second direction is perpendicular to the top surface of the native substrate; and
bonding the pixel structures of a plurality of the light-emitting chips to the bare wafer, with top surfaces of the light-emitting chips facing the bare wafer.

19. The pixel array according to claim 18, wherein the forming the pixel structures arranged at intervals on the native substrate comprises:
forming a patterned mask layer on the native substrate, the patterned mask layer comprising opening patterns arranged at intervals along the first direction, the opening patterns exposing part of the native substrate;
forming first semiconductor layers in the opening patterns, respectively, with top surfaces of the first semiconductor layers being flush and higher than a top surface of the patterned mask layer;
forming active layers covering outer surfaces of the first semiconductor layers, respectively, and arranged at intervals along the first direction; and
forming second semiconductor layers covering outer surfaces of the active layers, respectively, and arranged at intervals along the first direction; wherein each pixel structure is jointly formed by one first semiconductor layer, one active layer, and one second semiconductor layer that are sequentially stacked in a direction perpendicular to the native substrate, and a conductivity type of the first semiconductor layer is opposite to that of the second semiconductor layer.

20. The pixel array according to claim 18, wherein the forming the pixel structures arranged at intervals on the native substrate comprises:
forming a patterned mask layer on the native substrate, the patterned mask layer comprising opening patterns arranged at intervals along the first direction, the opening patterns exposing part of the native substrate;
forming first semiconductor layers in the opening patterns, respectively, with top surfaces of the first semiconductor layers being flush and higher than a top surface of the patterned mask layer;
forming an initial bonding isolation layer on the patterned mask layer, a top surface of the initial bonding isolation layer being flush with the top surfaces of the first semiconductor layers, the initial bonding isolation layer being located between adjacent first semiconductor layers that are arranged along the first direction;
forming active layers on the top surfaces of the first semiconductor layers, respectively; and
forming second semiconductor layers on top surfaces of the active layers, respectively; wherein each pixel structure is jointly formed by one first semiconductor layer, one active layer, and one second semiconductor layer that are sequentially stacked in a direction perpendicular to the native substrate, and a conductivity type of the first semiconductor layer is opposite to that of the second semiconductor layer.
